(19) United States
(12) Patent Application Publication
(10) Pub. No.: US 2020/0150231 A1
(43) Pub. Date: May 14, 2020

(54) POWER ADJUSTMENT METHOD AND LASER MEASUREMENT DEVICE

(71) Applicant: SZ DJI TECHNOLOGY CO., LTD., Shenzhen (CN)

(72) Inventors: Xiang LIU, Shenzhen (CN); Xiaoping HONG, Shenzhen (CN); Huan HE, Shenzhen (CN); Jiangbo CHEN, Shenzhen (CN)

(21) Appl. No.: 16/727,578

(22) Filed: Dec. 26, 2019

Related U.S. Application Data
(63) Continuation of application No. PCT/CN2017/114033, filed on Nov. 30, 2017.

(51) Int. Cl. G01S 7/484; G01S 7/497; H01S 5/042

(52) U.S. Cl. CPC G01S 7/484; H01S 5/0428; G01S 7/497

(57) ABSTRACT

A power adjustment method includes controlling a power detection circuit of a laser measurement device to detect a power of laser emitted from a laser emission circuit of the laser measurement device, obtaining a threshold power corresponding to the laser measurement device, and adjusting the power of the laser according to the threshold power.

### CROSS-REFERENCE TO RELATED APPLICATION

This application is a continuation of International Application No. PCT/CN2017/114033, filed on Nov. 30, 2017, the entire content of which is incorporated herein by reference.

### TECHNICAL FIELD

The present disclosure relates to the technical field of electronic technology and, more particularly, to a power adjustment method and a laser measurement device.

### BACKGROUND

A laser measurement device (e.g., a lidar) is a sensor system for obtaining three-dimensional (3D) information of the environment, instead of sensing only two-dimensional (2D) information of the environment like a camera. The principle of the laser measurement device is to actively emit a laser pulse signal to a measured object in the environment, detect a reflected pulse signal reflected by the measured object, and determine a distance between the measured object and the laser measurement device based on a time difference between emission of the laser pulse signal and detection of the reflected pulse signal. Combined with emission angle information of the laser pulse signal, 3D depth information is reconstructed.

A power of laser emitted by the laser measurement device should not exceed a threshold power. In an actual production process, before a batch of the laser measurement devices leave the factory, related parameters are adjusted according to statistical results of the powers of laser emitted by the batch of the laser measurement devices to ensure that the power of the laser emitted by each laser measurement device does not exceed the threshold power.

However, considering the inconsistency in circuit components, laser diodes, optical structures, and other components, the powers of laser emitted by different laser measurement devices in mass production are often different. If the relevant parameters are adjusted according to the statistical results of the powers of laser emitted by different laser measurement devices, the powers of laser emitted by some laser measurement devices are relatively smaller and the performances of these laser measurement devices are poor.

### SUMMARY

In accordance with the disclosure, there is provided a power adjustment method including controlling a power detection circuit of a laser measurement device to detect a power of laser emitted from a laser emission circuit of the laser measurement device, obtaining a threshold power corresponding to the laser measurement device, and adjusting the power of the laser according to the threshold power.

Also in accordance with the disclosure, there is provided a laser measurement device including a laser emission circuit configured to emit laser, a power detection circuit configured to detect a power of the laser, a processor couple to the laser emission circuit and the power detection circuit, and a memory coupled to the processor. The memory stores program instructions that, when being executed by the processor, cause the processor to control the power detection circuit to detect the power of the laser, obtain a threshold power corresponding to the laser measurement device, and adjust the power of the laser according to the threshold power.

### BRIEF DESCRIPTION OF THE DRAWINGS

In order to provide a clearer illustration of technical solutions of disclosed embodiments, the drawings used in the description of the disclosed embodiments are briefly described below. It will be appreciated that the disclosed drawings are merely examples. Other drawings can be conceived by those having ordinary skills in the art on the basis of the disclosed drawings without inventive efforts.

FIG. 1 is a schematic structural diagram of a laser sensor system consistent with embodiments of the disclosure.

FIG. 2 is a schematic diagram of a partial structure of a laser measurement device consistent with embodiments of the disclosure.

FIG. 3A is a schematic structural diagram of a laser measurement device consistent with embodiments of the disclosure.

FIG. 3B is a schematic structural diagram of a peak hold circuit consistent with embodiments of the disclosure.

FIG. 3C is a schematic structural diagram of another peak hold circuit consistent with embodiments of the disclosure.

FIG. 4A is a schematic structural diagram of another laser measurement device consistent with embodiments of the disclosure.

FIG. 4B is a schematic structural diagram of a widening circuit consistent with embodiments of the disclosure.

FIG. 5 is a schematic flow chart of a power adjustment method consistent with embodiments of the disclosure.

FIG. 6A is a schematic flow chart of another power adjustment method consistent with embodiments of the disclosure.

FIG. 6B is a schematic flow chart of another power adjustment method consistent with embodiments of the disclosure.

FIG. 7 is a schematic structural diagram of another laser measurement device consistent with embodiments of the disclosure.

### DETAILED DESCRIPTION OF THE EMBODIMENTS

In order to provide a clearer illustration of technical solutions of disclosed embodiments, example embodiments will be described with reference to the accompanying drawings.

A laser measurement device, for example, a lidar or laser rangefinder, is a sensor system for obtaining three-dimensional (3D) information of the environment, instead of sensing two-dimensional (2D) information of the environment like a camera. The principle of the laser measurement device is to actively emit a laser pulse signal to a measured object in the environment, detect a reflected pulse signal reflected by the measured object, and determine a distance between the measured object and the laser measurement device based on a time difference between the emission of the laser pulse signal and a detection of the reflected pulse signal. Combined with emission angle information of the laser pulse signal, 3D depth information can be reconstructed.

A measurement distance that the laser measurement device can achieve is related to a power of laser emitted by the laser measurement device. A greater power of the emitted laser corresponds to a longer maximum measurement distance. The measurement distance refers to a distance that the laser measurement device can measure. However, the laser measurement device generally has a threshold power. If the threshold power is exceeded, the laser measurement device may be damaged, and even a safety accident may be caused. For example, the threshold power of the laser measurement device can be a power specified in a preset safety specification standard. Therefore, the power of the laser emitted from the laser measurement device should not exceed the threshold power.

In order not to exceed the threshold power and to achieve the maximum power of the laser measurement device, the present disclosure provides a power adjustment method and a laser measurement device.

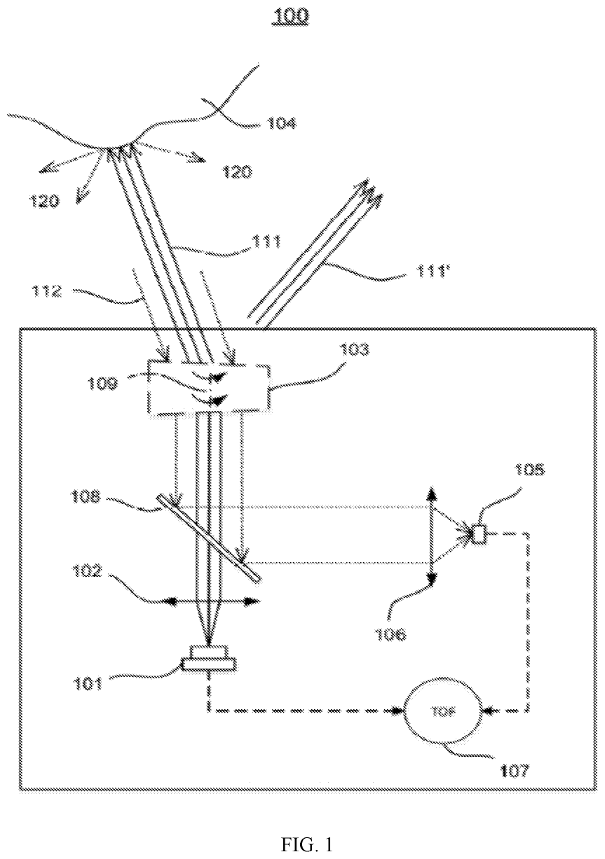

FIG. 1 is a schematic structural diagram of an example laser sensor system 100 consistent with the disclosure. As shown in FIG. 1, the laser sensor system 100 is configured to detect a distance between the laser sensor system 100 and a measured object 104 (also referred to as a “target object”). For example, the laser sensor system 100 may include a laser measurement device, such as a lidar, a laser rangefinder, or the like. The working principle can be to measure a time of propagation, i.e., time of flight (TOF), between the laser sensor system 100 and the measured object 104 to detect the distance between the measured object 104 and the laser sensor system 100.

The laser sensor system 100 can be implemented based on different solutions. In some embodiments, the laser sensor system 100 can be based on a coaxial solution, in which an exit light beam 111 and a return light beam 112 can share at least a part of an optical path. For example, the exit light beam 111 and the return light beam 112 can travel along the same optical path. In some other embodiments, the laser sensor system 100 may be based on other solutions, such as an off-axis solution, in which the exit light beam 111 and the return light beam 112 may be configured to travel along different optical paths.

As shown in FIG. 1, the laser sensor system 100 includes a light source 101 capable of generating the laser. For example, the laser may be a single laser pulse or a series of laser pulses, and the generated laser may be collimated light. Collimated light refers to light with parallel rays, which may not diffuse outwardly or have a small angle of diffusion during propagation.

In some embodiments, the light generated by a point source can be collimated. In the example shown in FIG. 1, a lens 102 is used to collimate the light generated by the light source 101. As another example, a mirror, such as a spherical mirror, a parabolic mirror, and/or the like, may be used to collimate the light generated by the point source.

As shown in FIG. 1, the collimated light can be directed to a light beam steering/scanning device 103 that can cause a deflection of an incident light. In some embodiments, the light beam steering/scanning device 103 can control a direction of the laser to scan an environment around the laser sensor system 100. For example, the light beam steering device 103 may include various optical elements, such as prisms, mirrors, gratings, optical phased arrays (e.g., liquid crystal control gratings), or any combination thereof. Each of these different optical elements can be rotated about a substantially common axis 109 (hereinafter referred to as a common axis) to turn light rays in different directions. That is, angles between rotation axes of different optical elements may be the same or slightly different. For example, the angles between the rotation axes of different optical elements can be 0.01 degrees, 0.1 degrees, 1 degree, 2 degrees, 5 degrees, and/or the like.

According to the coaxial solution shown in FIG. 1, once the exit light beam 111 illuminates the measured object 104, a back-reflected portion of the light can return to the laser sensor system 100 in a completely opposite direction. Therefore, when the coaxial solution is used, a transmission (or exit) field of view (FOV) of the laser sensor system 100 can be consistent with a reception FOV of the laser sensor system 100. Therefore, no dead zones exist even at a short distance from the laser sensor system 100.

In some embodiments, different structures can be used to achieve the coaxial system. For example, as show in FIG. 1, a beam splitter 108 is arranged between the light source 101 (together with the lens 102) and the light beam steering/scanning device 103.

As shown in FIG. 1, the collimated light can pass through the beam splitter 108 and incident on the light beam steering/scanning device 103. The light beam steering/scanning device 103 can then be controlled to turn the light toward different directions, such as directions 111 and 111′. The beam splitter 108 may be configured to redirect the return light beam incident on the beam splitter 108 to a detector 105. For example, the beam splitter 108 may include a mirror having an opening. The opening of the beam splitter 108 can allow the collimated light from the light source 101 to pass (and turn toward the light beam steering/scanning device 103), and a mirror portion of the beam splitter 108 can direct the return light beam 112 toward a receiving lens 106, which can focus the return light beam on the detector 105.

In some embodiments, the detector 105 may receive the return light beam and convert the return light beam into an electrical signal. For example, the detector 105 can include a receiving device having a highly sensitive semiconductor electronic devices, such as an avalanche photodiode (APD). The APD can use the photocurrent effect to convert light into electricity.

In some embodiments, a measurement circuit, such as a TOF circuit 107, may be configured to measure the TOF to detect the distance to the measured object 104. For example, the TOF circuit 107 can calculate the distance to the measured object 104 based on a formula t=2D/c. D is the distance between the laser sensor system 100 and the measured object 104, c is the speed of light, and t is a duration time of a round trip from the laser sensor system 100 to the measured object 104 and returned to the laser sensor system 100. Therefore, the laser sensor system 100 can measure the distance to the measured object 104 based on the time difference between the light source 101 generating the exit light beam 111 and the detector 105 receiving the return light beam 112.

In some embodiments, the emitted light can be generated by a laser diode in the nanosecond (ns) level. For example, the light source 101 can generate a laser pulse with a duration of approximately 10 ns, and the detector 105 can detect a return signal of the laser pulse with a similar duration. In addition, a receiving time of the laser pulse can be determined in a receiving process. For example, the receiving time can be determined by detecting a rising edge of the electrical pulse. In some embodiments, a multi-stage amplification process can be used in a detection process. Therefore, the laser sensor system 100 can use pulse receiving time information and pulse transmitting time information to calculate TOF information, and thus, determine the distance to the measured object 104.

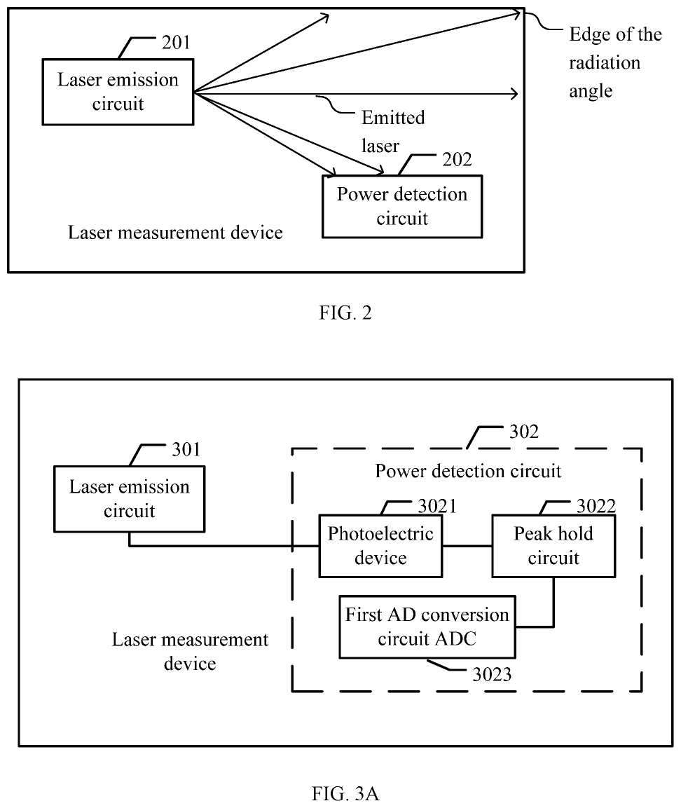

Hereinafter, a partial structure of an example laser measurement device consistent with the present disclosure is described. The laser measurement device may be, for example, the laser sensor system 100 in FIG. 1. FIG. 2 is a schematic diagram of the partial structure of the laser measurement device consistent with the disclosure. The laser measurement device shown in FIG. 2 includes a laser emission circuit 201 and a power detection circuit 202. Straight lines with an arrow shown in FIG. 2 represent the laser light emitted by the laser emission circuit 201. In some embodiments, the laser emission circuit in FIG. 2 may include the light source 101 in FIG. 1.

In some embodiments, the laser emission circuit 201 may include a signal driver, a laser diode, a power source, a diode, and the like, which is not limited herein. In some embodiments, the signal driver can generate a driving signal. A wider pulse width of the driving signal corresponds to a longer turn-on time of the laser diode and a larger power of the emitted laser. In some embodiments, if a voltage of a power supply is high, a current flowing through the laser diode when the laser diode is turned on can be large, and, and the power of the emitted laser can be large.

The power detection circuit 202 can be configured to detect the power of the emitted laser. The power of the laser emitted by the laser emission circuit 201 at an edge of its radiation angle can be relatively low, and in some embodiments, the laser at the edge can be discarded. In some embodiments, the power detection circuit 202 can use the discarded laser to measure the power of the laser, so as to reduce blocking of the emitted laser of the laser emission circuit 201 due to the power measurement.

In some embodiments, the optical structure may be configured to separate a part of the laser emitted from the laser emission circuit 201, e.g., through beam splitting. The separated part of the laser can be incident on the power detection circuit 202 located outside an emission optical path of the laser emission circuit 201 for measuring the power.

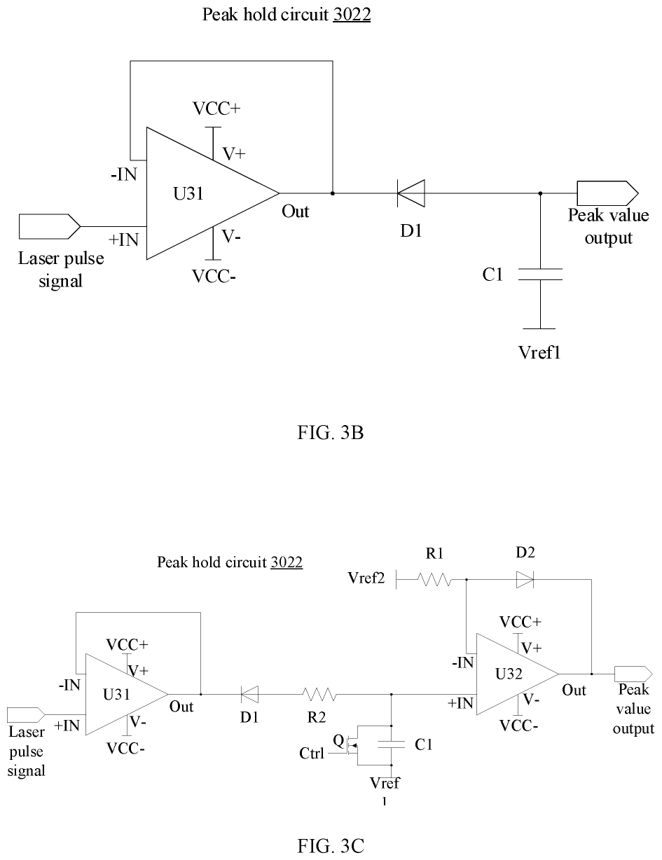

FIG. 3 is a schematic diagram of an overall structure of an example laser measurement device consistent with the disclosure. As shown in FIG. 3, the laser measurement device includes a laser emission circuit 301 and a power detection circuit 302. The power detection circuit 302 includes a photoelectric device 3021, a peak hold circuit 3022, and a first analog-to-digital (AD) conversion circuit (ADC) 3023.

The laser emission circuit 301 can emit laser at a preset emission direction, and the photoelectric device 3021 can detect the laser emitted by the laser emission circuit 301 and convert the optical signal into the electrical signal. In some embodiments, the converted electrical signal may be weak. The photoelectric device 3021 may input the electrical signal to the peak hold circuit 3022 for processing.

In some embodiments, the optical structure can separate a part of the emitted laser light and guide to the photoelectric device 3021. The photoelectric device 3021 can detect the optical signal of the part of the laser emitted from the laser emission circuit 301, and thus, the converted electrical signal may be weak. The electrical signal may also be referred to as a laser pulse signal obtained by the photoelectric device 3021.

In some embodiments, the first AD conversion circuit 3023 can obtain a sampling value according to a pulse amplitude. A corresponding relationship between the sampling value and the power of the laser emitted by the laser emission circuit 301 can be obtained according to an actual calibration. For example, an actual power of the emitted laser can be measured by an optical power meter at an emission port of the laser emission circuit 301, and a proportion relationship between the actual output power and the sampling value measured by the power detection circuit 302 can be obtained. The power of the laser emitted by the laser emission circuit 301 can be calculated according to the proportion relationship and the sampling value.

FIG. 3B is a schematic structural diagram of an example peak hold circuit 3022 consistent with the disclosure. As shown in FIG. 3B, the peak hold circuit 3022 includes a first diode D1 and a holding capacitor C1. A first terminal of the first diode D1 is configured to receive the laser pulse signal, and a second terminal of the first diode D1 is connected to a first terminal of the holding capacitor C1 and an output terminal of the peak hold circuit 3022. A second terminal of the holding capacitor C1 is configured to receive a reference level Vref1. The output terminal of the peak hold circuit 3022 is connected to the first AD converter 3023. The first AD converter 3023 can be configured to obtain a peak value of the laser pulse signal, thereby obtaining the pulse amplitude of the laser pulse signal.

In some embodiments, the peak hold circuit 3022 further includes a first operational amplifier U31. The first operational amplifier U31 includes a first input terminal +IN, a second input terminal −IN, an output terminal OUT, a positive power terminal V+, and a negative power terminal V−. The positive and negative power supply terminals V+ and V− of the first operational amplifier U31 are connected to positive and negative power supplies VCC+ and VCC−, respectively. The first input terminal +IN of the first operational amplifier U31 is configured to receive the laser pulse signal, the second input terminal −IN of the first operational amplifier U31 is electrically connected to the output terminal OUT of the first operational amplifier U31 and the first terminal of the first diode D1. The first operational amplifier U31 can be configured to amplify the laser pulse signal and output the amplified laser pulse signal to the first terminal of the first diode D1. In some embodiments, the peak hold circuit 3022 may further include a second resistor R2 electrically connected between the second terminal of the first diode D1 and the first terminal of the holding capacitor C1.

FIG. 3C is a schematic structural diagram of another example peak hold circuit 3022 consistent with the disclosure. In the example shown in FIG. 3C, the peak hold circuit 3022 further includes a second operational amplifier U32 and a first resistor R1. The second operational amplifier U32 includes a first input terminal +IN, a second input terminal −IN, an output terminal OUT, a positive power supply terminal V+, and a negative power supply terminal V−. The positive and negative power supply terminals V+ and V− of the second operational amplifier U32 are connected to the positive and negative power supplies VCC+ and VCC−, respectively. The first input terminal +IN of the second operational amplifier U32 is electrically connected to the first terminal of the holding capacitor C1. The second input terminal −IN of the second operational amplifier U32 is electrically connected to the first terminal of the first resistor R1 and the output terminal OUT of the second operational amplifier U32. The second terminal of the first resistor R1 is configured to receive a reference level Vref2. The second operational amplifier U32 can be configured to improve a load driving capability of subsequent circuits. The reference level Vref1 may be the same as the reference level Vref2.

In some embodiments, the peak hold circuit 3022 further includes a second diode D2. A first terminal of the second diode D2 is electrically connected to the second input terminal −IN of the second operational amplifier U32. A second terminal of the second diode D2 is electrically connected to the output terminal OUT of the second operational amplifier U32. A polarity of the second diode D2 can be opposite to that of the first diode D1. An on-state voltage drop of the first diode D1 can cause an error in the peak value of the output of the peak hold circuit 3022, and a magnitude of the error can be equal to the on-state voltage drop of the first diode Dl. Therefore, by setting the polarity of the second diode D2 to be opposite to the polarity of the first diode D1, a compensation for the error can be achieved.

If the peak hold circuit 3022 is configured to obtain the peak value of a negative pulse of the laser pulse signal, the first terminal of the first diode D1 can be a negative electrode, the second terminal of the second diode D2 can be a positive electrode, the first terminal of the second diode D2 can be a positive electrode, and the second terminal of the second diode D2 can be a negative electrode. If the peak hold circuit 3022 is configured to obtain the peak value of a positive pulse of the laser pulse signal, the first terminal of the first diode D1 can be a positive electrode, the second terminal of the second diode D2 can be a negative electrode, the first terminal of the second diode D2 can be a negative electrode, and the second terminal of the second diode D2 can be a positive electrode.

In some embodiments, the peak hold circuit 3022 further includes a controllable switch Q. The controllable switch Q can be connected in parallel with the holding capacitor C1, and configured to release a charge stored in the holding capacitor C1 after the AD converter 3023 completes a peak acquisition. The controllable switch Q includes a control signal input terminal Ctrl for receiving a control signal and being turned on or off according to the control signal. When the controllable switch Q is turned on, the charge stored in the holding capacitor C1 can be released.

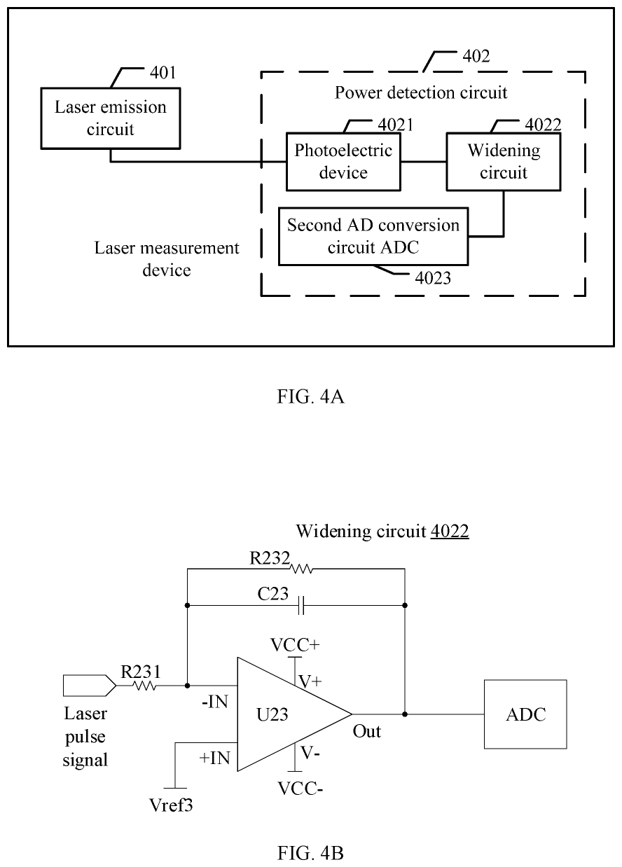

FIG. 4A is a schematic diagram of an overall structure of another example laser measurement device consistent with the disclosure. As shown in FIG. 4A, the laser measurement device includes a laser emission circuit 401 and a power detection circuit 402. The power detection circuit 402 includes a photoelectric device 4021, a widening circuit 4022, and a second AD conversion circuit (ADC) 4023.

The laser emission circuit 401 is similar to the laser emission circuit 301 in FIG. 3A, and detail descriptions thereof are omitted herein. The photoelectric device 4021 is similar to the photoelectric device 3021, and detail descriptions thereof are omitted herein.

The laser emission circuit 401 can emit the laser at the preset emission direction. The photoelectric device 4021 can detect the laser emitted from the laser emission circuit 301 and convert the optical signal into the electrical signal. In some embodiments, the converted electrical signal may be weak, and the photoelectric device 4021 may input the electrical signal to the widening circuit 4022 for processing.

The second AD converter 4023 can perform a digital sampling processing on the widened laser pulse signal at a relatively low sampling frequency, and calculate a pulse energy according to a result of the digital sampling processing to obtain the power of the laser emitted by the laser emission circuit 401. In some embodiments, the second AD conversion circuit 4023 can obtain the sampling value according to the result of digital sampling processing, and the sampling value and the power of the laser emitted by the laser emission circuit 401 can be obtained according to the actual calibration.

FIG. 4B is a schematic structural diagram of an example widening circuit 4022 consistent with the disclosure. The widening circuit 4022 can be configured to widen and amplify the laser pulse signal. In the example shown in FIG. 4B, the widening circuit 4022 includes a widening operational amplifier U23, a second input resistor R231, a feedback resistor R232, and a second feedback capacitor C23. A first input terminal +IN of the widening operational amplifier U23 is configured to receive a reference level Vref3, and a second input terminal −IN of the widening operational amplifier U23 is connected to one end of the second input resistor R231. Another end of the second input resistor R231 is configured to receive the laser pulse signal. A second input terminal −IN of the widening operational amplifier U23 is also connected to an output terminal OUT of the widening operational amplifier U23 through the feedback resistor R232 and the second feedback capacitor C23 connected in parallel to each other. Positive and negative power supply terminals V+ and V− of the widening operational amplifier U23 are connected to the positive and negative power supplies VCC+ and VCC−, respectively.

In some embodiments, the present disclosure also provides a laser measurement device for sensing external environmental information, such as distance information, angle information, reflection intensity information, velocity information, and the like, of an environmental target. The laser measurement device may include a lidar.

In some embodiments, the laser measurement device consistent with the disclosure can be applied to a mobile platform, and the laser measurement device can be installed on a platform body of the mobile platform. The mobile platform with the laser measurement device can measure the external environment, for example, measuring the distance between the mobile platform and an obstacle for obstacle avoidance and other purposes, and performing 2D or 3D mapping on the external environment.

In some embodiments, the mobile platform can include at least one of an unmanned aerial vehicle (UAV), an automobile, or a remote control vehicle. When the laser measurement device is applied to the UAV, the platform body can include a body of the UAV. When the laser measurement device is applied to the automobile, the platform body can include a body of the automobile. When the laser measurement device is applied to the remote control vehicle, the platform body can include a body of the remote control vehicle.

Embodiments of a power adjustment method will be described in detail below. The methods consistent with the disclosure can be applied to a laser measurement device including a laser emission circuit and a power detection circuit, for example, any one of the laser measurement devices described above in connection with FIGS. 1 to 4B.

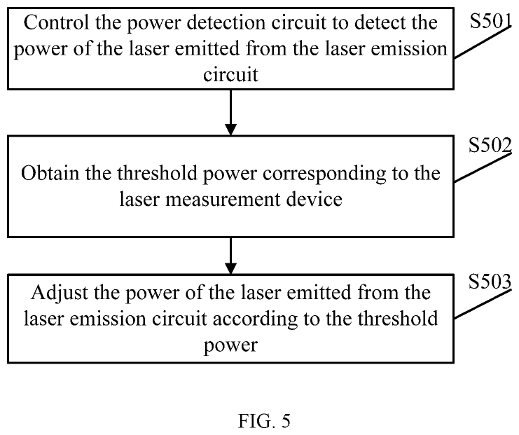

FIG. 5 is a schematic flow chart of an example power adjustment method consistent with the disclosure. A power adjustment can be performed by the power measurement device itself, or performed by a special processing device provided at the power measurement device or elsewhere.

As shown in FIG. 5, at S501, the power detection circuit is controlled to detect the power of the laser emitted from the laser emission circuit. The power detection circuit and the laser emission circuit can be, for example, any one of the power detection circuits and any one of the laser emission circuits described above in connection with FIGS. 2 to 4B.

The measurement distance that the laser measurement device can achieve is related to a power of laser emitted by the laser measurement device. A greater power of the emitted laser corresponds to a longer maximum measurement distance. In order to ensure safety of the laser measurement device, safety standards are generally set. The power of the laser emitted by the laser measurement device cannot exceed a power limit of the safety standard.

At S502, the threshold power corresponding to the laser measurement device is obtained. In some embodiments, the threshold power corresponding to the laser measurement device can be the power specified in the preset safety specification standard, and the power of the laser emitted by the laser measurement device cannot exceed the threshold power.

In some embodiments, the laser measurement device can store the threshold power in advance. When the power of the laser emitted from the laser emission circuit is detected by the power detection circuit, the stored threshold power can be obtained.

In some embodiments, the laser measurement device can also obtain the threshold power from peripheral devices (such as servers, terminals, UAVs, mobile platforms, or the like). For example, the laser measurement device can maintain communication with the peripheral device through a wireless link or a wired link, and obtain the threshold power from the peripheral device through a communication interface of the laser measurement device.

At S503, the power of the laser emitted from the laser emission circuit is adjusted according to the threshold power. The laser measurement device can adjust the power of the laser emitted from the laser emission circuit not to exceed the threshold power.

In some embodiments, the laser measurement device can adjust the power of the laser emitted from the laser emission circuit to be close to the threshold power. For example, the laser measurement device can use a certain power value lower than the threshold power as a maximum power value in accordance with the safety standard, and adjust the power of the laser emitted by the laser emission circuit to the maximum power value in accordance with the safety standard.

In some embodiments, adjusting the power of the laser emitted by the laser emission circuit according to the threshold power may include setting an adjustment range according to the threshold power, and adjusting the power of the laser emitted by the laser emission circuit to be within the adjustment range.

The adjustment range may refer to a range of power values that can be achieved after the power of the laser emitted from the laser emission circuit is adjusted. For example, the power of the laser emitted by the laser emission circuit can be 50 w, and the determined adjustment range can be 30 w to 38 w. After adjusting the power of the laser emitted by the laser emission circuit, the output power of the laser can be within the range from 30 w to 38 w.

In some embodiment, setting the adjustment range according to the threshold power and adjusting the power of the laser emitted from the laser emission circuit to be within the adjustment range can include determining a margin value between the threshold power and the power of the laser emitted by the laser emission circuit, setting the adjustment range according to the margin value, and adjusting the power of the laser emitted by the laser emission circuit to be within the adjustment range.

For example, the threshold power can be 36 w, and the power of the laser emitted by the laser emission circuit can be 50 w, then the margin value between the threshold power and the power of the laser emitted by the laser emission circuit can be 5 w. The laser measurement device may set the adjustment range to 33 w to 36 w to ensure that the difference between the adjustment range and the power of the laser emitted from the laser emission circuit is greater than or equal to the margin value.

In some embodiments, the margin value can be determined according to an environmental parameter. The environmental parameter can include a temperature and/or a degree of aging of a component. The component may refer to any one or more components included the laser measurement device.

The environmental parameter can affect the power of the laser emitted by the laser emission circuit. For example, if the temperature of the laser emission circuit is too high, the power of the laser emitted by the laser emission circuit may be reduced. In order to mitigate the influence of environmental parameter on the power of the laser emitted from the laser emission circuit, when setting the margin value between the power of the laser emitted from the laser emission circuit and the threshold power, the margin value can be set according to the environmental parameter. As such, if the power of the laser becomes larger or smaller when being affected by environmental parameter, the power of the laser can be dynamically adjusted to the maximum value that meets the safety standards to reduce the impact of environmental parameter on the power of the laser.

In some embodiments, adjusting the power of the laser emitted from the laser emission circuit to be within the adjustment range can include adjusting the pulse width of the driving signal or the power supply voltage to adjust the power of the laser emitted by the laser emission circuit to be within the adjustment range.

In some embodiments, the signal driver can be arranged in the laser emission circuit, and the signal driver can generate the driving signal. A wide pulse width of the driving signal corresponds to a large power of the emitted laser. A narrow pulse width of the driving signal corresponds to a small power of the emitted laser. Therefore, the pulse width of the driving signal can be narrowed to reduce the power of the emitted laser, and the pulse width of the driving signal can be adjusted to increase the power of the emitted laser.

In some embodiments, if the power supply voltage of the laser measurement device is high, the power of the emitted laser can be large, and if the power supply voltage of the laser measurement device is small, the power of the emitted laser output can be small. Therefore, the power supply voltage can be reduced to reduce the power of the emitted laser, and the power supply voltage can be increased to increase the power of the emitted laser.

In some embodiments, after adjusting the power of the laser emitted from the laser emission circuit according to the threshold power, the method further includes, if the power of the laser emitted by the laser emission circuit exceeds the threshold power, controlling the laser emission circuit to suspend the emission of the laser.

For example, after the power of the laser emitted from the laser emission circuit is adjusted according to the threshold power, if a problem occurs on a circuit structure of the laser measurement device and the power of the laser emitted from the laser emission circuit suddenly increases sharply, the power of the emitted laser can be reduced below the threshold power in real time, or the laser emission circuit can be controlled to suspend the emission of the laser.

In some embodiments, the power of the laser emitted by each laser measurement device can be actually measured before the laser measurement device leaves the factory, and the power of the laser emitted by each laser measurement device can be adjusted to the maximum power value that complies with safety standards.

Consistent with the disclosure, the laser measurement device can control the power detection circuit to detect the power of the laser emitted by the laser emission circuit, and adjust the power of the laser emitted by the laser emission circuit according to the threshold power. As such, the power of the emitted laser can be detected in real time, and the power of the laser emitted by the laser measurement device can be adjusted. Even if the adjusted power of the laser does not exceed the threshold power, the laser measurement device can reach the maximum power as much as possible, the distance measured by the laser measurement device can be increased, and the performance of the laser measurement device can be improved.

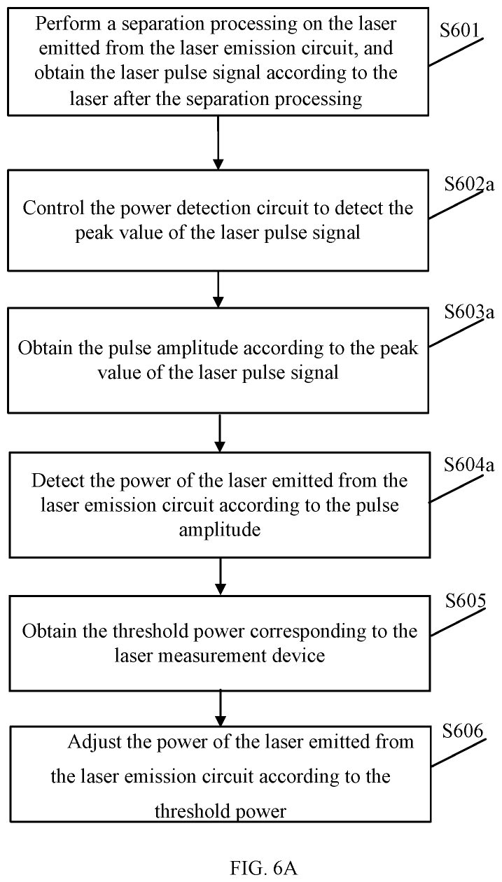

FIG. 6A is a schematic flow chart of another example power adjustment method consistent with the disclosure. As shown in FIG. 6A, at S601, a separation processing is performed on the laser emitted from the laser emission circuit, and the laser pulse signal is obtained according to the laser after the separation processing.

In some embodiments, the laser measurement device can use the optical structure to separate a part of the laser emitted from the laser emission circuit. The laser pulse signal can be obtained from the separated part of the laser. The optical structure may be any structure that can be used to separate the laser, which is not limited herein.

In some embodiments, the power of the laser emitted by the laser emission circuit at the edge of its radiation angle can be low, and in some embodiments, the laser at the edge can be used to obtain the laser pulse signal. The laser pulse signal may refer to a physical quantity representing the laser. The laser pulse signal may refer to a pulse signal generated according to the laser emitted from the laser emission circuit.

In some embodiments, the power detection circuit may further include a photoelectric device, and the laser pulse signal can be detected by the photoelectric device. The photoelectric device may be, for example, any one of the photoelectric devices described above in connection with FIGS. 3A and 4A. The photoelectric device can perform light sensing, and determine the power of the laser emitted by the laser emission circuit according to the signal of the photoelectric device. In some embodiments, the photoelectric device can be configured to perform the relevant processes implemented by the photoelectric devices described above in connection with FIGS. 3A and 4A.

The processes at S602a to S604a may be related processes for controlling the power detection circuit to detect the power of the laser emitted from the laser emission circuit.

At S602a, the power detection circuit is controlled to detect the peak value of the laser pulse signal. The peak value of the laser pulse signal may refer to a highest value of the signal in a signal period, or a difference between the highest value minus an average value and a lowest value minus the average value of the signal in the signal period.

In some embodiments, the laser measurement device can control the power detection circuit to detect a part of the laser emitted from the laser emission circuit, and obtain the peak value of the laser pulse signal of the part of the laser. In some embodiments, the laser measurement device may also control the power detection circuit to detect all of the laser emitted by the laser emission circuit from the laser emission port, and obtain the peak value of the laser pulse signal of all of the laser.

At S603a, the pulse amplitude is obtained according to the peak value of the laser pulse signal. In some embodiments, the power detection circuit can include a peak hold circuit and a first AD converter ADC. The peak hold circuit may be, for example, the peak hold circuit 3022 described above in connection with FIGS. 3A, 3B, and 3C, and the first AD converter ADC may be, for example, the first AD conversion circuit 3023 described above in connection with FIG. 3A.

In some embodiments, the peak hold circuit may include a diode, a holding capacitor, and the like. The peak hold circuit may further include other structures, which is not limited herein. In some embodiments, the first AD converter ADC can be configured to obtain the peak value of the pulse signal, thereby obtaining the pulse amplitude of the laser pulse signal. In some embodiments, the peak value of the laser pulse signal and the pulse amplitude can be obtained by the peak hold circuit and the first AD converter ADC.

At S604a, the power of the laser emitted from the laser emission circuit can be detected according to the pulse amplitude. The first AD converter ADC can detect the power of the laser emitted by the laser emission circuit according to the pulse amplitude. In some embodiments, the sampling value calculated by the first AD converter ADC has the corresponding relationship with the power of the laser emitted from the laser emission circuit, and the corresponding relationship can be obtained through the actual calibration.

For example, the optical power meter can be used to measure the actual output power of the laser at the emission port of the laser emission circuit, and obtain the proportion relationship between the actual output power and the sampled value measured by the first AD converter ADC. The power of the laser emitted by the laser emission circuit can be calculated according to the proportion relationship and the sampling value.

FIG. 6B is a schematic flow chart of another example power adjustment method consistent with the disclosure. As shown in FIG. 6B, controlling the power detection circuit to detect the power of the laser emitted by the laser emission circuit may further include the following processes.

At S602b, the power detection circuit is controlled to perform a widening process and an amplification process on the laser pulse signal. In some embodiments, the power detection circuit can include a widening circuit. The widening circuit can be configured to perform the widening process and the amplification process on the laser pulse signal. In some embodiments, the widening circuit may include a widening operational amplifier resistor, a feedback capacitor, and the like. For example, a structure of the widening circuit may be as shown in FIG. 4B, which is not limited here.

At S603b, the laser pulse signal after the widening processing and the amplification processing is digitally sampled, and the power of the laser emitted by the laser emission circuit is calculated according to the result of the digital sampling processing. In some embodiments, digitally sampling the laser pulse signal after the widening processing and the amplification processing, and calculating the power of the laser emitted by the laser emission circuit according to the result of the digital sampling processing can include: digitally sampling the laser pulse signal after the widening processing and the amplification processing to obtain the sampling value, and performing a calibration processing according to the sampling value to obtain the power of the laser emitted by the laser emission circuit.

In some embodiments, the power measurement circuit may further include a second AD converter ADC for performing the digital sampling processing. The output end of the widening circuit may be connected to the second AD converter ADC. After the laser pulse signal is widened and amplified by the widening circuit, the second AD converter ADC may be further digital sampling of the widened pulse signal at a low sampling rate. The calibration process can be performed according to the sampled value to obtain the power of the laser emitted by the laser emission circuit.

In some embodiments, the calibration process can include the actual calibration. In some embodiments, performing the calibration processing according to the sampling value to obtain the power of the laser emitted by the laser emission circuit can includes: obtaining the proportion relationship between the actual output power and the calculated power of the laser, and calibrating the sampling value according to the proportion relationship to obtain the power of the laser emitted by the laser emission circuit.

For example, the optical power meter can be used to measure the actual output power of the laser at the emission port of the laser emission circuit, and obtain the proportion relationship between the actual output power and the sampled value measured by the second AD converter ADC. The power of the laser emitted by the laser emission circuit can be calculated according to the proportion relationship and the sampling value.

Referring again to FIG. 6A, at S605, the threshold power corresponding to the laser measurement device is obtained.

At S606, the power of the laser emitted from the laser emission circuit is adjusted according to the threshold power.

The processes at S605 and S606 are similar to the processes at S502 and S503 described above, and detailed descriptions thereof are omitted here.

Consistent with the disclosure, the laser pulse signal can be obtained by separating the laser emitted from the laser emission circuit. The power of the laser emitted by the laser emission circuit can be detected by the power detection circuit according to the laser pulse signal. The power of the laser emitted by the laser emission circuit can be adjusted according to the threshold power. The power of the laser emitted can be detected in real time, and the power of the laser emitted by the laser measurement device can be adjusted, thereby improving the performance of the laser measurement device.

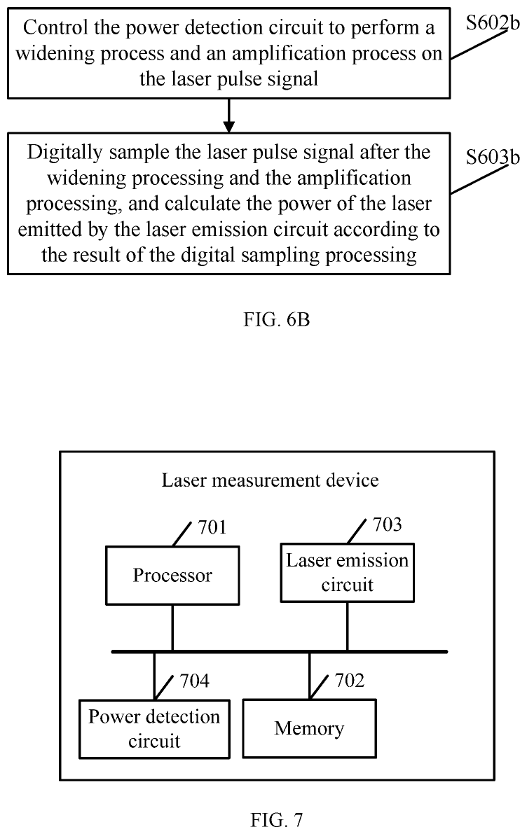

The present disclosure further provides another laser measurement device. FIG. 7 is a schematic structural diagram of another laser measurement device consistent with the disclosure. As shown in FIG. 7, the laser measurement device includes a processor 701, a memory 702, a laser emission circuit 703, and a power detection circuit 704.

The laser emission circuit 703 can be configured to emit laser. The power detection circuit 704 can be configured to detect the power of the laser emitted from the laser emission circuit 703. The memory 702 can be configured to store program instructions. The processor 701 can be configured to execute the program instructions stored in the memory 702. When executed by the processor 701, the program instructions can cause the processor to 701 control the power detection circuit 704 to detect the power of the laser emitted from the laser emission circuit 703, obtain the threshold power corresponding to the laser measurement device, and adjust the power of the laser emitted from the laser emission circuit 703 according to the threshold power.

In some embodiments, the processor 701 can be further configured to, when adjusting the power of the laser emitted from the laser emission circuit 703 according to the threshold power, set the adjustment range according to the threshold power, and adjust the power of the laser emitted by the laser emission circuit 703 to be within the adjustment range.

In some embodiments, the processor 701 can be further configured to, when setting the adjustment range according to the threshold power and adjusting the power of the laser emitted by the laser emission circuit 703 to be within the adjustment range, determine the margin value between the threshold power and the power of the laser emitted by the laser emission circuit 703, set the adjustment range according to the margin value, and adjust the power of the laser emitted by the laser emission circuit 703 to be within the adjustment range. In some embodiments, the margin value can be determined according to the environmental parameter. The environmental parameter can include the temperature and/or the degree of aging of a component.

In some embodiments, the processor 701 can be further configured to, after adjusting the power of the laser emitted from the laser emission circuit 703 according to the threshold power, control the laser emission circuit 703 to suspend the emission of the laser, if the power of the laser emitted by the laser emission circuit 703 exceeds the threshold power.

In some embodiments, the processor 701 can be further configured to, when adjusting the power of the laser emitted from the laser emission circuit 703 to be within the adjustment range, adjust the pulse width of the driving signal or the power supply voltage to adjust the power of the laser emitted by the laser emission circuit 703 to be within the adjustment range.

In some embodiments, the processor 701 can be further configured to, when controlling the power detection circuit 704 to detect the power of the laser emitted from the laser emission circuit 703, control the power detection circuit 704 to detect the peak value of the laser pulse signal, obtain the pulse amplitude according to the peak value of the laser pulse signal, and detect the power of the laser emitted from the laser emission circuit 703 according to the pulse amplitude. The laser pulse signal refers to a pulse signal generated by the laser emitted from the laser emission circuit 703.

In some embodiments, the power detection circuit 704 can include the peak hold circuit and the first AD conversion circuit ADC. The peak value of the laser pulse signal and the pulse amplitude can be obtained by the peak hold circuit and the first AD conversion circuit ADC.

In some embodiments, the processor 701 can be further configured to, when controlling the power detection circuit 704 to detect the power of the laser emitted from the laser emission circuit 703, control the power detection circuit 704 to perform the widening process and the amplification process on the laser pulse signal, digitally sample the laser pulse signal after the widening processing and the amplification processing, and calculate the power of the laser emitted by the laser emission circuit 703 according to the result of the digital sampling processing.

In some embodiments, the processor 701 can be further configured to, when digitally sampling the laser pulse signal after the widening processing and the amplification processing, and calculating the power of the laser emitted by the laser emission circuit 703 according to the result of the digital sampling processing, digitally sample the laser pulse signal after the widening processing and the amplification processing to obtain the sampling value, and perform the calibration processing according to the sampling value to obtain the power of the laser emitted by the laser emission circuit 703.

In some embodiments, the processor 701 can be further configured to, when performing the calibration processing according to the sampling value to obtain the power of the laser emitted by the laser emission circuit 703, obtain the proportion relationship between the actual output power and the calculated power of the laser, and calibrate the sampling value according to the proportion relationship to obtain the power of the laser emitted by the laser emission circuit 703.

In some embodiments, the power detection circuit 704 can include a widening circuit and a second AD conversion circuit ADC. The widening circuit can be configured to perform the widening process and the amplification process on the laser pulse signal. The second AD conversion circuit ADC can be configured to perform the digital sampling processing.

In some embodiments, the processor 701 can be further configured to perform the separation processing on the laser emitted from the laser emission circuit, and obtain the laser pulse signal according to the laser after the separation processing. In some embodiments, the power detection circuit 704 can further include a photoelectric device. The laser pulse signal can be detected by the photoelectric device.

For the sake of simplicity, embodiments of the methods described above are expressed as combinations of a series of actions. However, those skilled in the art can be appreciated that the present disclosure is not limited by the sequences of actions described above. Some actions may be performed in another order or simultaneously. Those skilled in the art can be appreciated that the embodiments described in the specification are merely exemplary, and the actions and modules involved are not necessarily required by the present disclosure.

Those skill in the art will appreciate that some or all of the processes of the methods described above can be implemented by hardware associated with program codes, such as an apparatus including a processor and a computer readable storage medium. The program codes can be stored in the computer readable storage medium. The program codes, when being executed by the processor, can cause the processor to perform a method consistent with the disclosure, such as one of the example methods described above. The computer readable storage medium can include any medium that can store the program codes, such as a read-only memory (ROM), a random access memory (RAM), a magnetic disk, an optical disk, or the like.

The power adjustment method and laser measurement device consistent with the present disclosure are described in detail above, and specific examples are used herein to explain the principle and implementation of the present disclosure. It is intended that the embodiments disclosed herein are merely for helping understand the method consistent with the present disclosure and its core ideas. Changes of the above-described embodiments and application scope may be made by those skilled in the art in light of the ideas of the disclosure. The description in the specification is not intended to limit the scope of the disclosure.

What is claimed is:

1. A power adjustment method comprising:
controlling a power detection circuit of a laser measurement device to detect a power of laser emitted from a laser emission circuit of the laser measurement device;
obtaining a threshold power corresponding to the laser measurement device; and
adjusting the power of the laser according to the threshold power.

2. The method of claim 1, wherein adjusting the power of the laser includes:
setting an adjustment range according to the threshold power; and
adjusting the power of the laser to be within the adjustment range.

3. The method of claim 2, wherein setting the adjustment range includes:
determining a margin value between the threshold power and the power of the laser; and
setting the adjustment range according to the margin value.

4. The method of claim 3, wherein the margin value is determined according to an environmental parameter, the environmental parameter including at least one of a temperature or a degree of aging of the device.

5. The method of claim 2, wherein adjusting the power of the laser to be within the adjustment range includes adjusting a pulse width of a driving signal or a power supply voltage to adjust the power of the laser to be within the adjustment range.

6. The method of claim 1, further comprising:
after adjusting the power of the laser, controlling the laser emission circuit to suspend emission of the laser in response to the power of the laser exceeding the threshold power.

7. The method of claim 1, wherein controlling the power detection circuit to detect the power of the laser includes:
controlling the power detection circuit to detect a peak value of a laser pulse signal generated by the laser;
obtaining a pulse amplitude according to the peak value of the laser pulse signal; and
determining the power of the laser according to the pulse amplitude.

8. The method of claim 7, wherein:
the power detection circuit includes a peak hold circuit and an analog-to-digital (AD) conversion circuit; and
the peak value of the laser pulse signal and the pulse amplitude are obtained through the peak hold circuit and the AD conversion circuit.

9. The method of claim 1, wherein controlling the power detection circuit to detect the power of the laser includes:
controlling the power detection circuit to perform a widening process and an amplification process on a laser pulse signal generated by the laser;
digitally sampling the laser pulse signal after the widening processing and the amplification processing; and
calculating the power of the laser according to a result of the digital sampling processing.

10. The method of claim 9, wherein:
digitally sampling the laser pulse signal includes digitally sampling the laser pulse signal after the widening processing and the amplification processing to obtain a sampling value; and
calculating the power of the laser includes performing a calibration processing according to the sampling value to obtain the power of the laser.

11. A laser measurement device comprising:
a laser emission circuit configured to emit laser;
a power detection circuit configured to detect a power of the laser;
a processor couple to the laser emission circuit and the power detection circuit; and
a memory coupled to the processor and storing program instructions that, when being executed by the processor, cause the processor to:
control the power detection circuit to detect the power of the laser;
obtain a threshold power corresponding to the laser measurement device; and
adjust the power of the laser according to the threshold power.

12. The device of claim 11, wherein the program instructions further cause the processor to:
set an adjustment range according to the threshold power; and
adjust the power of the laser to be within the adjustment range.

13. The device of claim 12, wherein the program instructions further cause the processor to:
determine a margin value between the threshold power and the power of the laser;
set the adjustment range according to the margin value; and
adjust the power of the laser to be within the adjustment range.

14. The device of claim 13, wherein the margin value is determined according to an environmental parameter, the environmental parameter including at least one of a temperature or a degree of aging of the device.

15. The device of claim 12, wherein the program instructions further cause the processor to:
adjust a pulse width of a driving signal or a power supply voltage to adjust the power of the laser to be within the adjustment range.

16. The device of claim 11, wherein the program instructions further cause the processor to:
after adjusting the power of the laser, control the laser emission circuit to suspend emission of the laser in response to the power of the laser exceeding the threshold power.

17. The device of claim 11, wherein the program instructions further cause the processor to:
control the power detection circuit to detect a peak value of a laser pulse signal generated by the laser;
obtain a pulse amplitude according to the peak value of the laser pulse signal; and
detect the power of the laser according to the pulse amplitude.

18. The device of claim 17, wherein:
the power detection circuit includes a peak hold circuit and an analog-to-digital (AD) conversion circuit; and
the program instructions further cause the processor to obtain the peak value of the laser pulse signal and the pulse amplitude through the peak hold circuit and the AD conversion circuit.

19. The device of claim 11, wherein the program instructions further cause the processor to:
control the power detection circuit to perform a widening process and an amplification process on a laser pulse signal generated by the laser;
digitally sample the laser pulse signal after the widening processing and the amplification processing; and
calculate the power of the laser according to a result of the digital sampling processing.

20. The device of claim 19, wherein the program instructions further cause the processor to:
digitally sample the laser pulse signal after the widening processing and the amplification processing to obtain a sampling value; and
perform a calibration processing according to the sampling value to obtain the power of the laser.

21. The device of claim 20, wherein the program instructions further cause the processor to:
obtain a proportion relationship between an actual output power and a calculated power of the laser; and
calibrate the sampling value according to the proportion relationship to obtain the power of the laser.
